(19) United States
(12) Patent Application Publication
(10) Pub. No.: US 2025/0380367 A1
(43) Pub. Date: Dec. 11, 2025

(54) ELECTRONIC DEVICE HAVING A DOUBLE-WALLED HOUSING THAT ACTS AS A THERMAL BARRIER

(71) Applicant: Sandisk Technologies, Inc., Milpitas, CA (US)

(72) Inventors: Raghavan Nagarajan, Bengaluru (IN); Hariharapandian S, Bengaluru (IN); Apratim Sanyal, Bangalore (IN)

(21) Appl. No.: 18/739,566

(22) Filed: Jun. 11, 2024

(51) Int. Cl. H05K 5/02

(52) U.S. Cl. CPC H05K 5/0209

(57) ABSTRACT

A double-walled housing of an electronic device includes an outer wall and an inner wall that is surrounded by the outer wall. The outer wall has a first surface and a second surface. The inner wall also has a first surface and a second surface and directly contains electronic components of the electronic device. The second surface of the outer wall is spaced apart from the first surface of the inner wall and define a cavity. The cavity is vacuum sealed and/or includes an insulating material, which causes the cavity to act as a thermal barrier. The thermal barrier reduces an amount of heat that is transferred from the electronic components of the electronic device to the outer wall of the double-walled housing. As a result, a touch-point temperature of the first surface of the outer wall is reduced when compared with conventional housings.

### BACKGROUND

As demand for electronic devices increases, so do the demands for increased performance and capabilities, but in smaller packages. Increased performance and capabilities often means adding additional electronic components. However, as more electronic components are added to the electronic device, the more heat is generated. The heat that is generated by the electronic components is typically dissipated to a housing of the electronic device, which causes a touch-point temperature of the housing to increase.

It is difficult to maintain optimal functionality in smaller form factor electronic devices while maintaining a desired touch-point temperature of the housing. For example, as electronic components shrink in size, there is a balance between maximizing power and efficiency of the electronic device while ensuring an outer surface of the housing of the electronic device does not exceed certain surface level temperatures.

Accordingly, it would be advantageous for an electronic device to have features that reduce an amount of heat that is transferred from the internal electronic components of the electronic device to the housing of the electronic device.

### SUMMARY

The present disclosure describes an electronic device having a double-walled housing. The double-walled housing at least partially surrounds various electronic components of the electronic device. The double-walled housing protects the electronic components from damage and also acts as a thermal barrier for heat generated by the electronic components. As a result, an outside surface of the housing is cooler to the touch when compared with housings of current electronic devices.

The double-walled housing of the present disclosure includes an outer wall and an inner wall. The outer wall has a first surface (e.g., an outer surface) and a second surface (e.g., an inner surface). Likewise, the inner wall has a first surface (e.g., an outer surface) and a second surface (e.g., an inner surface). The second surface of the outer wall faces, is parallel or substantially parallel to, the first surface of the inner wall. The second surface of the outer wall and the first surface of the inner wall define a cavity. In an example, the cavity is vacuum sealed which causes the cavity to act as a thermal barrier. In another example, the cavity includes an insulating material which also causes the cavity to act as a thermal barrier.

The thermal barrier reduces an amount of heat that is transferred from the electronic components to the outer wall of the double-walled housing. As a result, the touch-point temperature of the first surface of the outer wall is reduced when compared with conventional housings.

Accordingly, examples of the present disclosure describe an electronic device that includes a housing that at least partially surrounds one or more electronic components. In an example, the housing includes an outer wall having a first surface and a second surface opposite the first surface. The housing also includes an inner wall opposite the outer wall. The inner wall has a first surface and a second surface opposite the first surface. The first surface of the inner wall faces the second surface of the outer wall and the second surface of the outer wall and the first surface of the inner wall define a cavity. In an example, a thermal barrier is provided within the cavity which insulates the outer wall from heat generated by the one or more electronic components.

Other examples describe an electronic device that includes a printed circuit board (PCB) and at least one hardware component mounted on the PCB. The electronic device also includes a double-walled housing. The double-walled housing has an inner wall at least partially surrounding the PCB and the at least one hardware component and an outer wall surrounding the inner wall. The outer wall also forms an outside surface of the housing. In an example, the outer wall and inner wall define a cavity between the outer wall and the inner wall and a thermal barrier is provided within the cavity.

Still other examples describe an electronic device that includes at least one hardware component mounted on a PCB. A double-walled housing at least partially surrounds the PCB. In an example, the double-walled housing includes a first wall and a second wall surrounding the first wall. The second wall forms an outside surface of the double-walled housing and the first wall and the second wall define a cavity. An insulation means is provided within the cavity. The insulation means acts as a thermal barrier against heat generated by the at least one hardware component.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

Non-limiting and non-exhaustive examples are described with reference to the following Figures.

FIG. 1A illustrates an electronic device having a double-walled housing according to an example.

FIG. 1B illustrates a side-view of the electronic device of FIG. 1A according to an example.

FIG. 2A illustrates a cross-section view of an electronic device having a double-walled housing that defines a cavity that is vacuum sealed and acts as a heat barrier according to an example.

FIG. 2B illustrates a cross-section view of an electronic device of FIG. 2A in which the cavity includes an insulating material according to an example.

FIG. 2C illustrates a cross-section view of an electronic device of FIG. 2A in which the cavity includes an insulating material and is vacuum sealed according to an example.

FIG. 3 illustrates a cross-section view of an electronic device having a double-walled housing according to another example.

FIG. 4 illustrates a cross-section view of an electronic device having a double-walled housing according to yet another example.

### DETAILED DESCRIPTION

In the following detailed description, references are made to the accompanying drawings that form a part hereof, and in which are shown by way of illustrations specific embodiments or examples. These aspects may be combined, other aspects may be utilized, and structural changes may be made without departing from the present disclosure. Examples may be practiced as methods, systems or devices. Accordingly, examples may take the form of a hardware implementation, an entirely software implementation, or an implementation combining software and hardware aspects. The following detailed description is therefore not to be taken in a limiting sense, and the scope of the present disclosure is defined by the appended claims and their equivalents.

As technology continues to evolve, the demand for small-sized products with higher performance capabilities is increasing. However, it is difficult to achieve and/or maintain optimal functionality within compact dimensions while also addressing surface thermal concerns associated with heightened performance.

For example, in order to achieve higher performance, an electronic device typically needs additional electronic components. As electronic components are added to the electronic device, it becomes increasingly difficult to maintain desired touch-point temperature thresholds. This is especially true for small form factor electronic devices.

For example, when heat is generated by the electronic components of an electronic device, the heat is typically transferred to the housing of the electronic device. The heat increases the surface temperature of the housing of the electronic device. However, it is desirable to keep a surface temperature of the electronic device below a maximum surface temperature threshold.

To address the above, the present disclosure describes a double-walled housing for an electronic device. In an example, the electronic device is a removable data storage device, such as, for example, a USB data storage device. Although a removable data storage device is specifically described, the double-walled housing may be used for various types of electronic devices.

As will be explained in greater detail herein, the double-walled housing at least partially surrounds various electronic components of the electronic device. The double-walled housing protects the electronic components from damage and also acts as a thermal barrier against heat generated by the electronic components. As a result, an outside surface of the housing of the electronic device is cooler to the touch when compared with housings of current electronic devices.

The double-walled housing includes an outer wall and an inner wall. The outer wall has a first surface (e.g., an outer surface) and a second surface (e.g., an inner surface) opposite the first surface. The inner wall has a first surface (e.g., an outer surface) and a second surface (e.g., an inner surface) opposite the first surface. The second surface of the outer wall faces the first surface of the inner wall. Additionally, the second surface of the outer wall and the first surface of the inner wall are spaced apart from each other to define a cavity. The cavity acts as a thermal barrier which prevents heat from being transferred from the electronic components to the first surface (e.g., the outer surface) of the outer wall.

In one example, the cavity is vacuum sealed or acts as a vacuum chamber. In another example, the cavity includes an insulating material. In yet another example, the cavity is vacuum sealed and includes the insulating material. Regardless of whether the cavity includes the insulating material and/or is vacuum sealed, the thermal barrier causes the temperature of the first surface of the outer wall to be reduced when compared with conventional housings that do not implement the double-walled design shown and described herein.

Accordingly, many technical benefits may be realized including, but not limited to, enabling small form factor electronic devices to comply with thermal touch-point requirements without sacrificing performance capabilities; ensuring the housing of small form factor electronic devices are comfortable to the touch of individuals; and reducing or eliminating the need for additional firmware and/or hardware components for thermal management purposes.

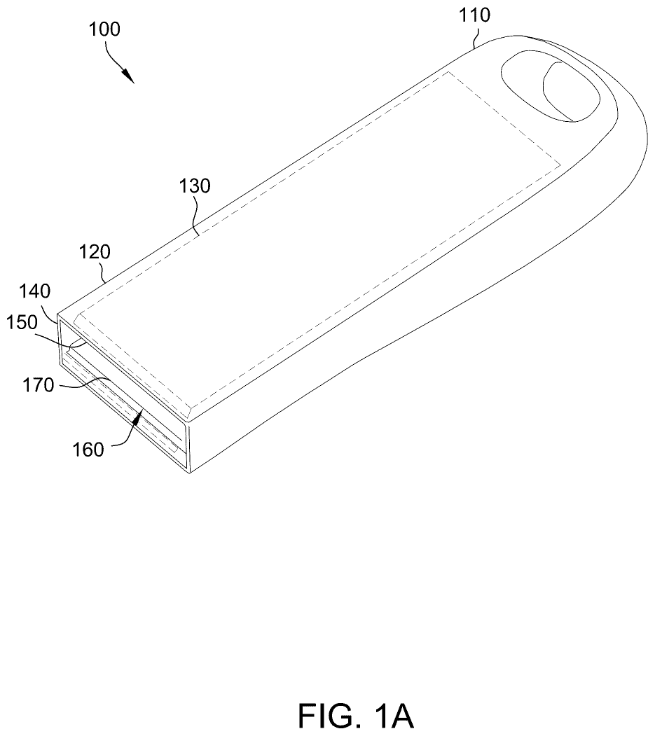

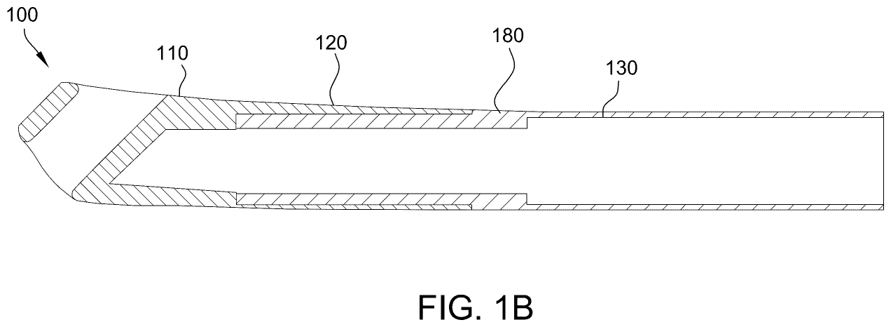

These and other examples will be described in more detail with respect to FIG. 1A-FIG. 4.

FIG. 1A illustrates an electronic device 100 having a double-walled housing 110 according to an example. In the example shown, the electronic device 100 is a removable data storage device, such as, for example, a universal serial bus (USB) data storage device. Although a removable data storage device is shown and described, the double-walled housing 110 described herein may be used in a variety of different electronic devices.

In an example, the double-walled housing 110 of the electronic device 100 includes an outer wall 120 and an inner wall 130 (shown in phantom). The outer wall 120 includes a first surface 140 (e.g., an outer surface) and a second surface 150 opposite the first surface 140. The outer wall 120 at least partially surrounds or contains the inner wall 130.

In an example and as will be shown in greater detail herein, the inner wall 130 also includes a first surface (e.g., an outer surface) and a second surface (e.g., an inner surface). The second surface of the inner wall 130 is opposite the first surface of the inner wall 130. The inner wall 130 at least partially surrounds the electronic components of the electronic device 100. For example, a second surface of the inner wall 130 directly surrounds a printed circuit board (PCB) and/or various electronic components of the electronic device 100 that are mounted on or are otherwise coupled to the PCB.

While the second surface of the inner wall 130 directly surrounds the PCB and/or the electronic components of the electronic device 100, the first surface of the inner wall 130 is opposite the second surface 150 of the outer wall 120. In an example, the first surface of the inner wall 130 and the second surface of the outer wall 120 are spaced apart from one another such that a gap or a cavity (e.g., cavity 180 FIG. 1B) is formed between the outer wall 120 and the inner wall 130.

In an example, the cavity acts as a thermal barrier for heat that is generated by the electronic components when the electronic device 100 is in use. The thermal barrier reduces or prevents a surface temperature of the outer wall 120 of the housing 110 from being influenced or affected by the internal temperature of the electronic device 100 though convection and/or conduction. Conduction is the transfer of heat through direct contact between materials. Convection involves the transfer of heat through the movement of fluids (liquids or gases).

In an example, the cavity extends at least partially along the length and/or width of the double-walled housing 110. Additionally, in examples, a first portion of the cavity has a first thickness while a second portion of the cavity has a second thickness.

For example and referring to FIG. 1B, FIG. 1B illustrates a side-view of the electronic device 100 of FIG. 1A according to an example. It is understood that similarly numbered and/or named components may function in a substantially similar fashion. Redundant explanation of these components has been omitted for clarity.

In the example shown in FIG. 1B, the cavity 180 is formed by a space between the outer wall 120 and the inner wall 130. However, in this example, a first portion of the cavity 180 (e.g., at or near a proximal end of the electronic device 100) has a first thickness and a second portion of the cavity 180 (e.g., at or near a distal end of the electronic device 100) has a second thickness that is less than the first thickness. In an example, the first thickness is between 0.4 millimeters (mm) and 0.7 mm although other thicknesses may be used. Additionally, in an example, the second thickness is between 0.2 mm and 0.3 mm although other thicknesses may be used. In an example, the first portion and the second portion are separate portions. In another example, the first portion and the second portion are part of a whole, single portion.

In an example, the cavity 180, or portions of the cavity follows a shape of the double-walled housing 110. For example, if the double-walled housing 110 is curved, the cavity 180, or portions of the cavity 180 are also curved. In other example, the cavity 180 or portions of the cavity 180 are planar.

In an example, the cavity 180 is vacuum sealed. In examples in which the cavity 180 is vacuum sealed, the absence of air molecules in the vacuum minimizes the transmission of heat through conduction and/or convection. Without a medium like air between the outer wall 120 and the inner wall 130, the transfer of heat through conduction is significantly reduced.

In another example, the cavity 180 includes an insulating material. In an example, the insulating material is foam or another insulating material. The vacuum or insulating material disrupts convective heat transfer by minimizing the movement of air molecules. This prevents the loss or gain of heat through the movement of air between the inner wall 130 and the outer wall 120. In yet another example, the cavity include insulating material and is vacuum sealed.

Referring back to FIG. 1A, in an example, the double-walled housing 110 also includes or defines an aperture or an opening 160. In an example, a connector 170 is disposed within (or extends from) the opening 160. The connector 170 enables the electronic device 100 to be removably connected to a computing device.

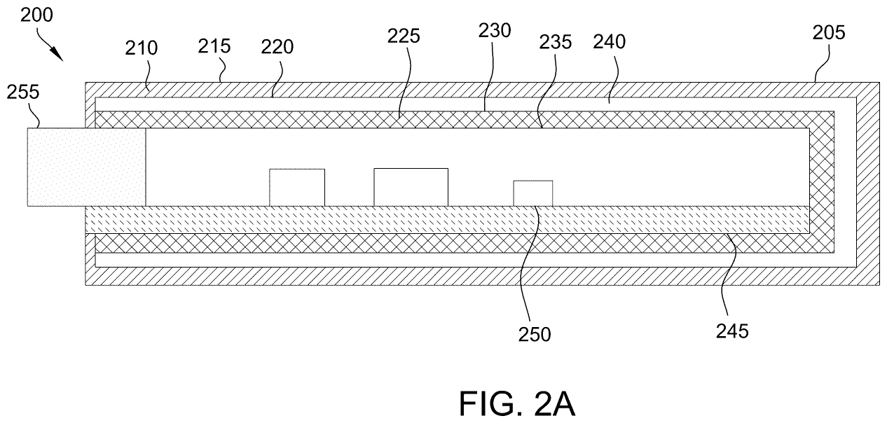

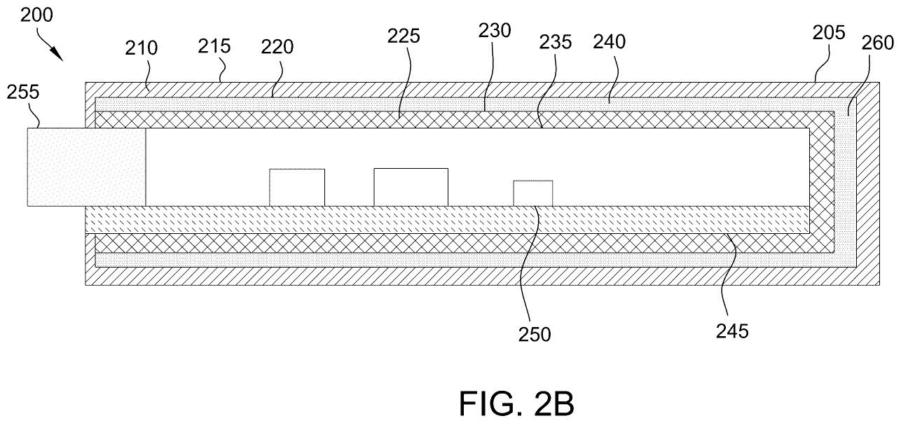

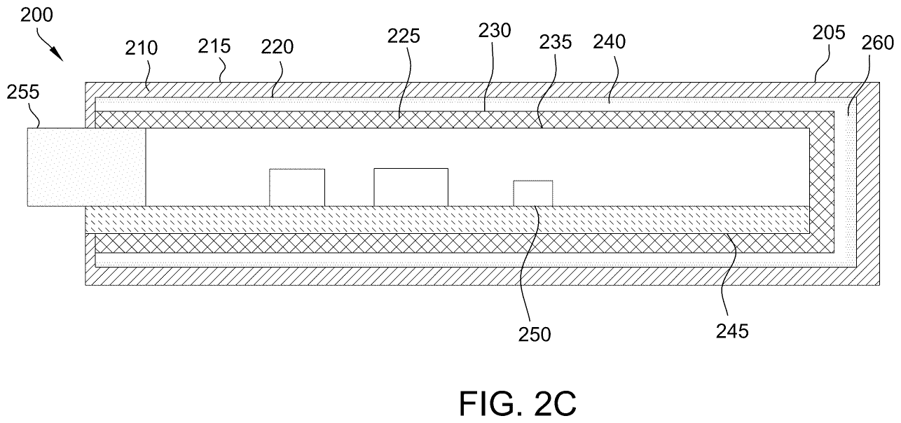

FIG. 2A illustrates a cross-section view of an electronic device 200 having a double-walled housing 205 that defines a cavity 240 that is vacuum sealed and acts as a heat barrier according to an example. In an example, the electronic device 200 is similar to the electronic device 100 shown and described herein with respect to FIG. 1A.

In an example, the double-walled housing 205 of the electronic device 200 includes an outer wall 210 (or a first wall) and an inner wall 225 (or a second wall). The outer wall 210 has a first surface 215 (or an outer surface) and a second surface 220 (or an inner surface) that is opposite the first surface 215.

A distance between the first surface 215 and the second surface 220 define a thickness of the outer wall 210. In an example, the outer wall 210 has a thickness of between 0.5 mm and 1.5 mm. Although a thickness of 0.5 mm and 1.5 mm is specifically mentioned, the outer wall 210 may have any desired thickness.

In an example, each of the first surface 215 and the second surface 220 of the outer wall 210 are planar. As such, the thickness of the of the outer wall 210 from a proximal end of the double-walled housing 205 to a distal end of the double-walled housing 205 is uniform. However, in other examples, at least one of the first surface 215 or the second surface 220 is not planar. As such, the thickness of the outer wall 210 increases or decreases from the proximal end of the double-walled housing 205 to a distal end of the double-walled housing 205.

In the example shown in FIG. 2A, the outer wall 210 extends completely around the electronic device 200. However, in other examples, the outer wall 210 may be comprised of separate pieces. For example, the outer wall 210 may include a top section (or a first section) and a bottom section (or a second section).

Like the outer wall 210, the inner wall 225 has a first surface 230 (or an outer surface) and a second surface 235 (or an inner surface) that is opposite the first surface 230. A distance between the first surface 230 and the second surface 235 define a thickness of the inner wall 225. In an example, the inner wall 225 has a thickness of between 0.5 mm and 1 mm or more. Although a thickness of between 0.5 mm and 1 mm is specifically mentioned, the inner wall 225 may have any desired thickness.

In an example, each of the first surface 230 and the second surface 235 are planar. As such, the thickness of the of the inner wall 225 from a proximal end of the double-walled housing 205 to a distal end of the double-walled housing 205 is uniform. However, in other examples, at least one of the first surface 230 or the second surface 235 is not planar. As such, the thickness of the inner wall 225 increases or decreases from the proximal end of the double-walled housing 205 to a distal end of the double-walled housing 205.

In an example, the inner wall 225 is completely surrounded by the outer wall 210. For example, the first surface 230 of the inner wall 225 is completely surrounded by the outer wall 210. In other examples, the inner wall 225 is partially surrounded by the outer wall 210. In some examples, the inner wall 225 is a single, unitary piece. In other examples, the inner wall 225 includes different sections (e.g., a top section and a bottom section).

The inner wall 225 completely (or partially) surrounds various electronic components 250 that are mounted on a PCB 245 of the electronic device 200. For example, the second surface 235 of the inner wall 225 faces the PCB 245 and the electronic components 250 such that the inner wall 225 directly contains the electronic components 250. In some examples, the inner wall 225 also completely surrounds the PCB 245. However, in other examples, a distal end of the PCB 245 may be exposed below a connector 255 or may otherwise be exposed as including part of the connector 255. In an example, the PCB 245 is placed on, or directly contacts, at least a portion of the second surface 235 of the inner wall 225.

In an example, the electronic components 250 include one or more memory dies (e.g., NAND memory dies), one or more controllers, one or more transistors, one or more capacitors, one or more resistors, and so on. Although specific electronic components 250 are mentioned, the electronic device 200 can include any number and/or types of electronic components 250.

In an example, the first surface 230 of the inner wall 225 faces the second surface 220 of the outer wall 210. Additionally, the first surface 230 of the inner wall 225 is spaced apart or separated from, the second surface 220 of the outer wall 210. As a result, a cavity 240 is defined between the first surface 230 of the inner wall 225 and the second surface 220 of the outer wall 210. In an example, the cavity 240 has a thickness of 0.2 mm to 0.7 mm or more. In an example, a first portion of the cavity 240 has a first thickness (e.g., 0.2 mm) and a second portion of the cavity 240 has a second thickness (e.g., 0.7 mm). Although a thickness of between 0.2 mm and 0.7 mm is specifically mentioned, the cavity 240 may have any desired thickness.

The cavity 240 acts as a thermal barrier for heat that is generated by the electronic components 250. In the example shown in FIG. 2A, the cavity 240 is vacuum sealed or forms a vacuum chamber. In another example, such as shown in FIG. 2B, the cavity 240 includes an insulating material 260 (e.g., foam or other material). In yet another example, such as shown in FIG. 2C, the cavity 240 includes an insulating material 260 and is vacuum sealed. Regardless of whether the cavity 240 is vacuum sealed and/or includes an insulating material 260, the cavity 240 prevents or restricts heat from reaching the first surface 215 of the outer wall 210. As such, the touch-point temperature of the outer wall 210 is cooler when compared with electronic devices that do not include a double-walled housing such as the one described herein.

For example, a USB drive that does not include or implement a double-walled housing may have a touch-point temperature of up sixty-seven degrees Celsius. However, a USB drive that includes the double-walled housing 205 shown and described herein has a touch-point temperature of sixty degrees Celsius. Although specific touch-point temperatures are given, these are for example purposes only and are used to illustrate that the double-walled housing of the present disclosure is effective in reducing the touch-point temperature of a housing of an electronic device.

As briefly discussed above, in an example, the electronic device 200 also includes a connector 255. The connector 255 may be an internal connector (such as shown in FIG. 1A) or the connector 255 may at least partially extend from an opening defined by the outer wall 210 and/or the inner wall 225 with the PCB 245 defining a lower boundary. In some examples, heat that is generated by the electronic components 250 is dissipated though the connector 255 (e.g., when the electronic device is not in use and/or is not connected to a computing device).

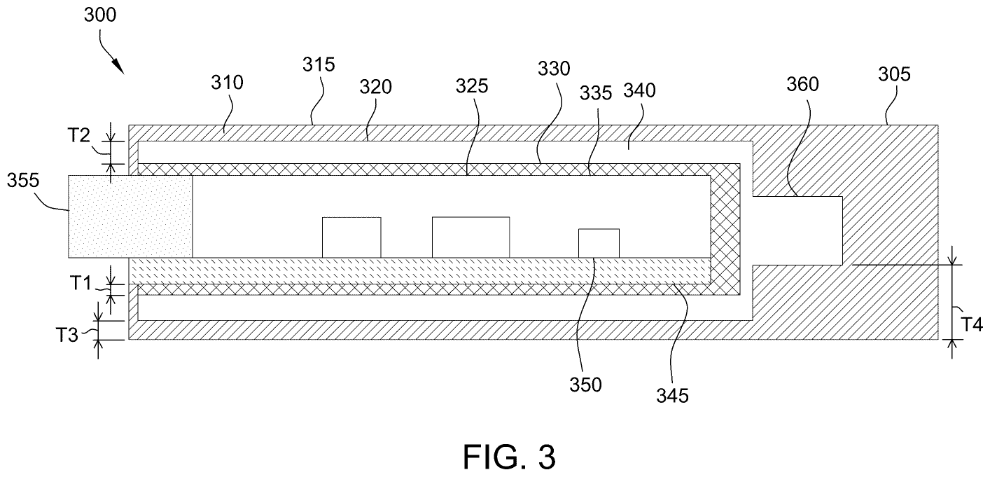

FIG. 3 illustrates a cross-section view of an electronic device 300 having a double-walled housing 305 according to another example. In an example, the electronic device 300 is similar to the electronic device 100 shown and described with respect to FIG. 1A and/or the electronic device 200 shown and described with respect to FIG. 2. It is understood that similarly numbered and/or named components may function in a substantially similar fashion. Redundant explanation of these components has been omitted for clarity.

For example, the double-walled housing 305 of the electronic device 300 includes an outer wall 310 having a first surface 315 and a second surface 320 opposite the first surface 315. The double-walled housing 305 also includes an inner wall 325 having a first surface 330 and a second surface 335 opposite the first surface 330. The outer wall 310 at least partially surrounds the inner wall 325 and the inner wall 325 directly contains a PCB 345 and electronic components 350 of the electronic device 300.

Like the previous examples, the first surface 330 of the inner wall 325 faces the second surface 320 of the outer wall 310 and define a cavity 340. The cavity 340 acts as a thermal barrier for heat that is generated by the electronic components 350 such as previously described. However, in this example, the inner wall 325 has a first thickness (T1), the cavity 340 has a second thickness (T2) and the outer wall 310 has a third thickness (T3). In an example, the first thickness (T1), the second thickness (T2) and the third thickness (T3) are different from each other.

In yet another example, a first portion of the outer wall 310 has the third thickness (T3) while a second portion of the outer wall 310 has a fourth thickness (T4) that is greater than the third thickness. For example, the outer wall 310 has a stair-step configuration 360 such as shown in FIG. 3. Although a stair-step configuration 360 is shown and described, the thickness of the outer wall 310 can linearly increase or decrease as a result of a sloping configuration.

In some examples, different portions of the inner wall 325 may also have different thicknesses. For example, and depending on a length of the PCB 345, a height of one or more of the electronic components 350 and/or a number/arrangement of the electronic components 350, the inner wall 325 can have a stair-step configuration, a sloping configuration and so on. For example, it may be desirable to have a top surface of one or more of the electronic components 350 contact the second surface 335 of the inner wall 325. As such, a thickness of the inner wall 325 may be adjusted or changed based on a height of at least one electronic component 350.

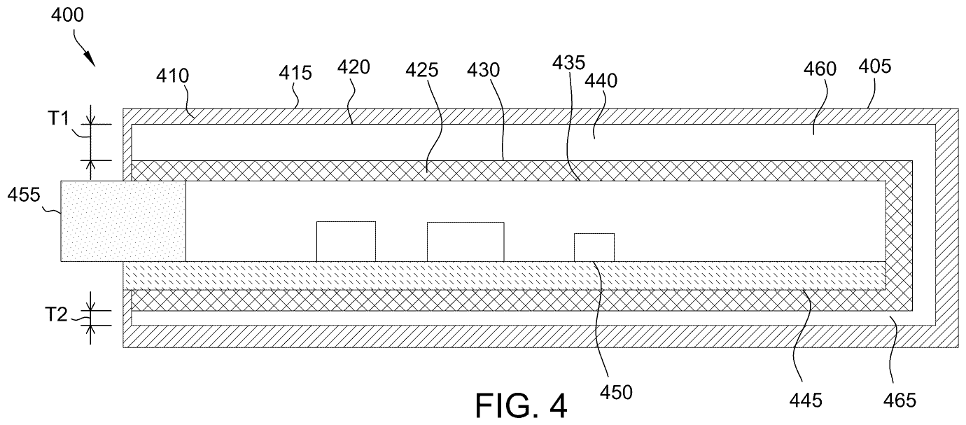

FIG. 4 illustrates a cross-section view of an electronic device 400 having a double-walled housing 405 according to yet another example. In an example, the electronic device 400 is similar to the electronic device 100 shown and described with respect to FIG. 1A and/or the electronic device 200 shown and described with respect to FIG. 2. It is understood that similarly numbered and/or named components may function in a substantially similar fashion. Redundant explanation of these components has been omitted for clarity.

For example, the double-walled housing 405 of the electronic device 400 includes an outer wall 410 having a first surface 415 and a second surface 420 opposite the first surface 415. The double-walled housing 405 also includes an inner wall 425 having a first surface 430 and a second surface 435 opposite the first surface 430. The outer wall 410 at least partially surrounds the inner wall 425 and the inner wall 425 directly contains a PCB 445 and/or electronic components 450 of the electronic device 400.

Like the previous examples, the first surface 430 of the inner wall 425 faces the second surface 420 of the outer wall 410 and define a cavity 440. The cavity 440 acts as a thermal barrier for heat that is generated by the electronic components 450 such as previously described. However, in this example a first portion 460 of the cavity 440 has a first thickness (T1) while a second portion 465 of the cavity 440 has a second thickness (T2) that is less than the first thickness (T1). For example, the first portion 460 of the cavity 440 that is above the electronic components 450 has an increased thickness when compared with the second portion 465 that is adjacent the PCB 450.

In another example, the reverse is true. For example, the first portion 460 of the cavity 440 that is above the electronic components 450 has the second thickness while the second portion 465 that is below the PCB 445 has the first thickness that is greater than the second thickness.

In the various examples described herein, the various components of the double-walled housing (e.g., the cavity, the outer wall and the inner wall) have been described as having various thicknesses. In an example, the thickness of the various components varies based, at least in part, on an orientation in which the electronic device 400 is in when operating. For example, a first portion of the cavity on a first side of the electronic device may be thicker (or thinner) if the first side of the electronic device (or if electronic components of the electronic device) faces a first direction (e.g., a downward direction) when the electronic device is attached to computing device or is otherwise operating. In other examples, the thickness of the various components is based, at least in part, on a type of the electronic device.

Based on the above, examples of the present disclosure describe an electronic device, comprising: a housing at least partially surrounding one or more electronic components, the housing comprising: an outer wall having a first surface and a second surface opposite the first surface; and an inner wall opposite the outer wall, the inner wall having a first surface and a second surface opposite the first surface, wherein the first surface of the inner wall faces the second surface of the outer wall and wherein the second surface of the outer wall and the first surface of the inner wall define a cavity; and a thermal barrier provided within the cavity, the thermal barrier insulating the outer wall from heat generated by the one or more electronic components. In an example, the thermal barrier is an insulating material. In an example, the thermal barrier is a vacuum chamber. In an example, the inner wall at least partially surrounds the one or more electronic components and a printed circuit board (PCB) on which the one or more electronic components are placed. In an example, the inner wall has a first thickness and the outer wall has a second thickness that is greater than the first thickness. In an example, the outer wall surrounds the inner wall. In an example, the thermal barrier has a uniform thickness. In an example, a first portion of the thermal barrier has a first thickness and a second portion of the thermal barrier has a second thickness that is different from the first thickness.

Examples also describe an electronic device, comprising: a printed circuit board (PCB); at least one hardware component mounted on the PCB; and a double-walled housing, comprising: an inner wall at least partially surrounding the PCB and the at least one hardware component; an outer wall surrounding the inner wall and forming an outside surface of the housing, the outer wall and inner wall defining a cavity between the outer wall and the inner wall; and a thermal barrier provided within the cavity. In an example, the thermal barrier is an insulation material. In an example, the thermal barrier is vacuum sealed. In an example, the inner wall has a first thickness and the outer wall has a second thickness that is greater than the first thickness. In an example, the electronic device is a removable data storage device and wherein the electronic device further comprises a connecter extending from a distal end of the double-walled housing. In an example, the thermal barrier has a uniform thickness. In an example, a first portion of the thermal barrier has a first thickness and a second portion of the thermal barrier has a second thickness that is different from the first thickness.

Other examples describe an electronic device, comprising: at least one hardware component mounted on a printed circuit board (PCB); and a double-walled housing at least partially surrounding the PCB, the double-walled housing, comprising: a first wall; a second wall surrounding the first wall, the second wall forming an outside surface of the double-walled housing, the first wall and the second wall defining a cavity; and an insulation means provided within the cavity, the insulation means acting as a thermal barrier against heat generated by the at least one hardware component. In an example, the insulation means is an insulating material. In an example, the insulation means is formed by vacuum sealing the cavity. In an example, the insulation means has a uniform thickness. In an example, a first portion of the insulation means has a first thickness and a second portion of the insulation means has a second thickness that is different than the first thickness.

The description and illustration of one or more aspects provided in the present disclosure are not intended to limit or restrict the scope of the disclosure in any way. The aspects, examples, and details provided in this disclosure are considered sufficient to convey possession and enable others to make and use the best mode of claimed disclosure.

The claimed disclosure should not be construed as being limited to any aspect, example, or detail provided in this disclosure. Regardless of whether shown and described in combination or separately, the various features (both structural and methodological) are intended to be selectively rearranged, included or omitted to produce an embodiment with a particular set of features. Having been provided with the description and illustration of the present application, one skilled in the art may envision variations, modifications, and alternate aspects falling within the spirit of the broader aspects of the general inventive concept embodied in this application that do not depart from the broader scope of the claimed disclosure.

References to an element herein using a designation such as “first,” “second,” and so forth does not generally limit the quantity or order of those elements. Rather, these designations may be used as a method of distinguishing between two or more elements or instances of an element. Thus, reference to first and second elements does not mean that only two elements may be used or that the first element precedes the second element. Additionally, unless otherwise stated, a set of elements may include one or more elements.

Terminology in the form of “at least one of A, B, or C” or “A, B, C, or any combination thereof” used in the description or the claims means “A or B or C or any combination of these elements.” For example, this terminology may include A, or B, or C, or A and B, or A and C, or A and B and C, or 2A, or 2B, or 2C, or 2A and B, and so on. As an additional example, “at least one of: A, B, or C” is intended to cover A, B, C, A-B, A-C, B-C, and A-B-C, as well as multiples of the same members. Likewise, “at least one of: A, B, and C” is intended to cover A, B, C, A-B, A-C, B-C, and A-B-C, as well as multiples of the same members.

Similarly, as used herein, a phrase referring to a list of items linked with “and/or” refers to any combination of the items. As an example, “A and/or B” is intended to cover A alone, B alone, or A and B together. As another example, “A, B and/or C” is intended to cover A alone, B alone, C alone, A and B together, A and C together, B and C together, or A, B, and C together.

What is claimed is:

1. An electronic device, comprising:
a housing at least partially surrounding one or more electronic components, the housing comprising:
an outer wall having a first surface and a second surface opposite the first surface; and
an inner wall opposite the outer wall, the inner wall having a first surface and a second surface opposite the first surface, wherein the first surface of the inner wall faces the second surface of the outer wall and wherein the second surface of the outer wall and the first surface of the inner wall define a cavity; and
a thermal barrier provided within the cavity, the thermal barrier insulating the outer wall from heat generated by the one or more electronic components.

2. The electronic device of claim 1, wherein the thermal barrier is an insulating material.

3. The electronic device of claim 1, wherein the thermal barrier is a vacuum chamber.

4. The electronic device of claim 1, wherein the inner wall at least partially surrounds the one or more electronic components and a printed circuit board (PCB) on which the one or more electronic components are placed.

5. The electronic device of claim 1, wherein the inner wall has a first thickness and the outer wall has a second thickness that is greater than the first thickness.

6. The electronic device of claim 1, wherein the outer wall surrounds the inner wall.

7. The electronic device of claim 1, wherein the thermal barrier has a uniform thickness.

8. The electronic device of claim 1, wherein a first portion of the thermal barrier has a first thickness and a second portion of the thermal barrier has a second thickness that is different from the first thickness.

9. An electronic device, comprising:
a printed circuit board (PCB);
at least one hardware component mounted on the PCB; and
a double-walled housing, comprising:
an inner wall at least partially surrounding the PCB and the at least one hardware component;
an outer wall surrounding the inner wall and forming an outside surface of the housing, the outer wall and inner wall defining a cavity between the outer wall and the inner wall; and
a thermal barrier provided within the cavity.

10. The electronic device of claim 9, wherein the thermal barrier is an insulation material.

11. The electronic device of claim 9, wherein the thermal barrier is vacuum sealed.

12. The electronic device of claim 9, wherein the inner wall has a first thickness and the outer wall has a second thickness that is greater than the first thickness.

13. The electronic device of claim 9, wherein the electronic device is a removable data storage device and wherein the electronic device further comprises a connecter extending from a distal end of the double-walled housing.

14. The electronic device of claim 9, wherein the thermal barrier has a uniform thickness.

15. The electronic device of claim 9, wherein a first portion of the thermal barrier has a first thickness and a second portion of the thermal barrier has a second thickness that is different from the first thickness.

16. An electronic device, comprising:
at least one hardware component mounted on a printed circuit board (PCB); and
a double-walled housing at least partially surrounding the PCB, the double-walled housing, comprising:
a first wall;
a second wall surrounding the first wall, the second wall forming an outside surface of the double-walled housing, the first wall and the second wall defining a cavity; and
an insulation means provided within the cavity, the insulation means acting as a thermal barrier against heat generated by the at least one hardware component.

17. The electronic device of claim 16, wherein the insulation means is an insulating material.

18. The electronic device of claim 16, wherein the insulation means is formed by vacuum sealing the cavity.

19. The electronic device of claim 16, wherein the insulation means has a uniform thickness.

20. The electronic device of claim 16, wherein a first portion of the insulation means has a first thickness and a second portion of the insulation means has a second thickness that is different than the first thickness.
